(19) United States
(12) Patent Application Publication
(10) Pub. No.: US 2026/0140449 A1
(43) Pub. Date: May 21, 2026

(54) LIQUID PROCESSING APPARATUS

(71) Applicant: Tokyo Electron Limited, Tokyo (JP)

(72) Inventors: Junghyun KIM, Hwaseong-si (KR); Koshi MUTA, Koshi City (JP); Daiki TAKAHASHI, Koshi City (JP); Kohei KAWAKAMI, Koshi City (JP); Satoshi SHIMMURA, Koshi City (JP); Kenta SHIBASAKI, Koshi City (JP); Shota UEYAMA, Koshi City (JP); Tetsushi MIYAMOTO, Koshi City (JP)

(21) Appl. No.: 19/446,258

(22) Filed: Jan. 12, 2026

Related U.S. Application Data
(63) Continuation of application No. 18/346,287, filed on Jul. 3, 2023.

(30) Foreign Application Priority Data
Jul. 5, 2022 (JP) 2022-108470

(51) Int. Cl. G03F 7/16

(52) U.S. Cl. CPC G03F 7/162

(57) ABSTRACT

A liquid processing apparatus that applies a coating liquid onto a substrate, includes: a substrate holder that holds and rotates the substrate; a coating liquid supplier that applies the coating liquid to the substrate; a cup provided to surround the substrate; and a solvent supplier that supplies a solvent for the coating liquid to a coating liquid collector. The cup includes: an outer cup arranged outside the substrate holder; an inner cup arranged on an inner peripheral side of the outer cup below the substrate holder and having a downwardly-extending wall; an exhaust path provided between the outer and inner cups; a cylindrical wall portion provided below the inner cup and having an upwardly-opened exhaust port communicating with the exhaust path; and the coating liquid collector arranged below the wall of the inner cup with a gap between the coating liquid collector and a lower end of the wall.

### CROSS-REFERENCE TO RELATED APPLICATION

This application is a continuation of U.S. patent application Ser. No. 18/346,287, filed Jul. 3, 2023, which claims the benefit of priority from Japanese Patent Application No. 2022-108470, filed on Jul. 5, 2022, the entire contents of each are incorporated herein by reference in its entirety.

### TECHNICAL FIELD

The present disclosure relates to a liquid processing apparatus.

### BACKGROUND

Patent Document 1 discloses a liquid processing apparatus that applies a coating liquid onto a substrate. This liquid processing apparatus includes: a substrate holder that holds and rotates the substrate; a coating liquid supplier that applies the coating liquid to the substrate held by the substrate holder; a cup arranged outside the substrate holder so as to surround the substrate held by the substrate holder; an exhaust path provided between the substrate holder and an inner peripheral surface of the cup; a coating liquid collector provided above the exhaust path so as to cover the exhaust path and including a vertically-communicating opening; a solvent supplier that supplies a solvent for the coating liquid to the coating liquid collector; and a relay located above the coating liquid collector and protruding from the inner peripheral surface of the cup toward the coating liquid collector.

### PRIOR ART DOCUMENTS

### Patent Documents

Patent Document 1: Japanese Patent Laid-Open Publication No. 2019-145561

### SUMMARY

According to one embodiment of the present disclosure, a liquid processing apparatus that applies a coating liquid onto a substrate, includes: a substrate holder configured to hold and rotate the substrate; a coating liquid supplier configured to supply the coating liquid to the substrate held by the substrate holder; a cup provided to surround the substrate held by the substrate holder; and a solvent supplier configured to supply a solvent for the coating liquid to a coating liquid collector, wherein the cup includes: an outer cup arranged outside the substrate holder; an inner cup arranged on an inner peripheral side of the outer cup and below the substrate holder, the inner cup having a downwardly-extending wall; an exhaust path provided between the outer cup and the inner cup; a cylindrical wall portion provided below the inner cup and having an upwardly-opened exhaust port communicating with the exhaust path; and the coating liquid collector arranged below the downwardly-extending wall of the inner cup with a gap between the coating liquid collector and a lower end of the downwardly-extending wall, wherein the coating liquid collector is fixed to the cylindrical wall portion.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a longitudinal cross-sectional view schematically illustrating a configuration of a resist coating apparatus according to the present embodiment.

FIG. 2 is a transversal cross-sectional view schematically illustrating the configuration of the resist coating apparatus according to the present embodiment.

FIG. 3 is a transversal cross-sectional view of a cup for explaining a cylindrical mesh ring.

FIG. 4 is a perspective view of the cylindrical mesh ring.

FIG. 5 is a longitudinal cross-sectional view of the cup for explaining the cylindrical mesh ring.

FIG. 6 is a view illustrating an example of a flow of a solvent supplied to the cylindrical mesh ring.

FIG. 7 is an explanatory view for explaining an example of a fixing structure of the cylindrical mesh ring.

FIG. 8 is an explanatory view for explaining a fixing portion between the cylindrical mesh ring and an attachment member.

FIG. 9 is an enlarged view of portion A of FIG. 8.

FIG. 10 is a view illustrating an example of a flow of the solvent supplied to the cylindrical mesh ring.

FIG. 11 is a longitudinal cross-sectional view of the cup for explaining a liquid receiver applied to the cylindrical mesh ring.

FIG. 12 is a view illustrating an example of flows of the solvent supplied to the cylindrical mesh ring.

FIGS. 13A to 13D are views illustrating a configuration example of the liquid receiver applied to the cylindrical mesh ring.

FIG. 14 is a perspective view of the mesh ring for explaining another shape example of openings in the cylindrical mesh ring.

FIGS. 15A to 15C are views illustrating examples of states of the solvent remaining in the openings.

FIG. 16 is a longitudinal cross-sectional view of a cup for explaining an annular mesh ring.

FIG. 17 is a transversal cross-sectional view of the cup for explaining the annular mesh ring.

FIG. 18 is a view illustrating an example of flows of a solvent supplied to the annular mesh ring.

FIG. 19 is an explanatory view for explaining the vicinity of a fixing portion between the annular mesh ring and the attachment member.

FIG. 20 is an explanatory view for explaining another shape example of the annular mesh ring.

FIG. 21 is a transversal cross-sectional view of a cup for explaining an annular plate.

FIG. 22 is a view illustrating an example of flows of a solvent supplied to the annular plate.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

For example, in a photolithography of a manufacturing process of semiconductor devices, a coating process in which a predetermined coating liquid is applied onto a semiconductor wafer (hereinafter referred to as a “wafer”) as a substrate to form a coating film such as an antireflection film or a resist film is performed.

In the coating process described above, a so-called spin coating method is widely used, in which a coating film is formed on a wafer by supplying a coating liquid from a nozzle to the wafer under rotation and spreading the coating liquid over the wafer by virtue of a centrifugal force. A rotary liquid processing apparatus for performing the spin coating method is provided with a container, called a cup, in order to prevent the coating liquid scattered from a surface of the rotating wafer from scattering to the surroundings. In the cup, evacuation is performed from the bottom thereof so as to prevent the outside of the cup from being contaminated by the flying of the coating liquid in the form of mist, which is scattered from the edge of the rotating wafer.

However, in recent years, there is a case where a coating film having a large film thickness needs to be formed on a wafer using a coating liquid such as a high-viscosity resist liquid. In the case of using such a high-viscosity coating liquid, the coating liquid may be dropped from the edge of the wafer and be partially solidified in a filamentous form when the wafer coated with the coating liquid is rotated to spread the coating liquid. Further, a plurality of coating liquids solidified in a filamentous form (hereinafter referred to as filamentous foreign substances) may be generated in the course of performing the coating process. These filamentous foreign substances may be entangled with each other to form flocculent foreign substances.

There is a concern that these filamentous or flocculent foreign substances may clog an exhaust path. In particular, since the exhaust path in the vicinity of the inner bottom of the cup has many narrower portions than the exhaust path at the upper portion of the cup, it is easy to be clogged with the foreign substances. When the exhaust path is clogged with the foreign substances, a desired exhaust pressure required for exhausting the interior of the cup may not be obtained. Thus, for example, the mist-like coating liquid may fly upward of the cup, which contaminates the outside of the cup.

Therefore, a technique according to the present disclosure prevents an exhaust path from being clogged due to foreign substances generated when performing a spin coating process on a substrate.

Hereinafter, a liquid processing apparatus according to the present embodiment will be described with reference to the drawings. In addition, in this specification and the accompanying drawings, elements having substantially the same functional configuration will be denoted by the same reference numerals, and redundant explanations thereof will be omitted.

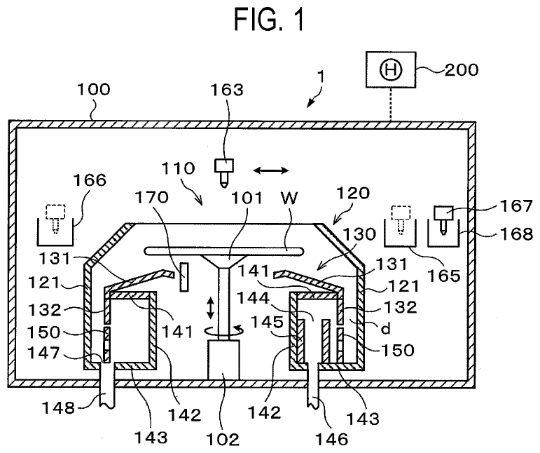

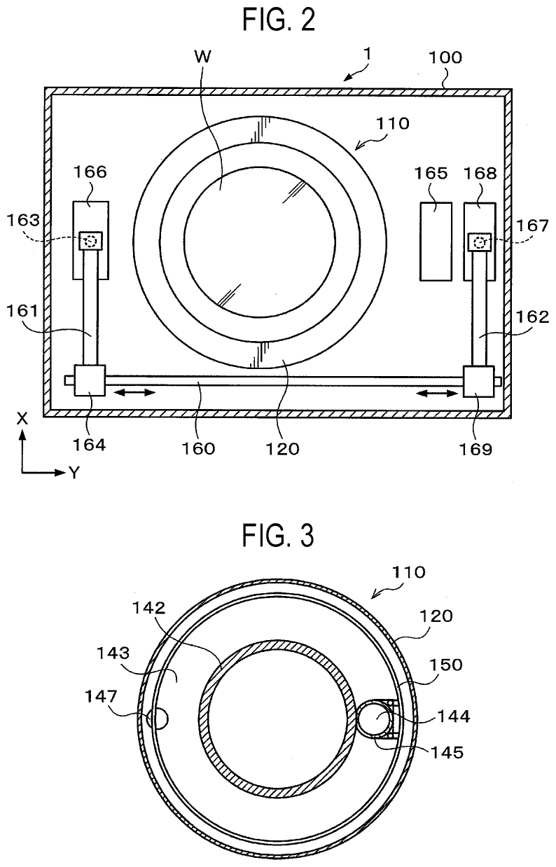

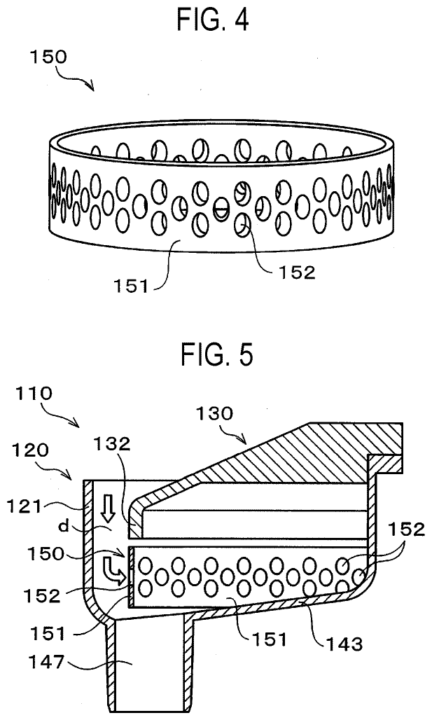

FIGS. 1 and 2 are a longitudinal cross-sectional view and a transversal cross-sectional view schematically illustrating a configuration of a resist coating apparatus 1 as the liquid processing apparatus, respectively. FIG. 3 is a transversal cross-sectional view of a cup 110 for explaining a mesh ring 150 as a coating liquid collector. FIG. 4 is a perspective view of the mesh ring 150.

As illustrated in FIGS. 1 and 2, the resist coating apparatus 1 includes a processing container 100 having a hermetically-sealable interior. A loading/unloading port (not illustrated) for a wafer W as a substrate is formed in a side surface of the processing container 100. A spin chuck 101 as a substrate holder that holds and rotates the wafer W is provided within the processing container 100. The spin chuck 101 may be rotated at a predetermined speed by a chuck driver 102 such as a motor. Further, the chuck driver 102 is provided with a lifting drive mechanism such as a cylinder, so that the spin chuck 101 may be moved up and down.

Further, the cup 110, which accommodates the spin chuck 101 and is exhausted from the bottom thereof, is provided within the processing container 100. The cup 110 receives and collects a liquid scattered or dropping from the wafer W. The cup 110 includes an outer cup 120 as an outer cup arranged outside the spin chuck 101 so as to surround the wafer W held by the spin chuck 101, and an inner cup 130 as an inner cup located on an inner peripheral side of the outer cup 120.

A sidewall 121 as a downwardly-extending cylindrical wall is provided at a lower portion of the outer cup 120. Further, the inner cup 130 includes an annular inclined wall 131 which is inclined down from an inner peripheral end toward an outer peripheral end thereof, and a sidewall 132 as a cylindrical wall extending down from the outer peripheral end of the inclined wall 131. The inclined wall 131 is arranged below the spin chuck 101 and receives the liquid dropping from the wafer W. The sidewall 132 is arranged so as to face an inner peripheral surface of the sidewall 121 of the outer cup 120. A gap is formed between the sidewall 121 and the sidewall 132 to constitute an exhaust path d.

A circular ring-shaped horizontal member 141, a cylindrical vertical member 142, and a circular ring-shaped bottom member 143 located at the bottom of the cup 110 are provided below the inner cup 130. A space surrounded by these members 141, 142 and 143, and the sidewall 132 of the inner cup 130 described above is defined within the cup 110. A cylindrical wall portion 145 having an exhaust port 144 that is in communication with the exhaust path d is provided within the space.

The cylindrical wall portion 145 extends in the vertical direction (height direction) of the cup 110, and the exhaust port 144 is open upward. An exhaust pipe 146 is connected to the bottom member 143 at a lower end of the cylindrical wall portion 145. That is, an exhaust flow in the cup 110 passes through the cylindrical wall portion 145 and is discharged from the exhaust path d.

A liquid discharge port 147 for discharging the collected liquid therethrough is formed in the bottom member 143 between the sidewall 121 of the outer cup 120 and the vertical member 142. A liquid discharge pipe 148 is connected to the liquid discharge port 147.

The mesh ring 150 as a coating liquid collector is provided below the sidewall 132 of the inner cup 130. The mesh ring 150 collects a resist liquid between the sidewall 132 of the inner cup 130 and the bottom member 143. A material of the mesh ring 150 is, for example, a metal such as stainless steel, but is not particularly limited as long as it has chemical resistance to solvents.

The mesh ring 150 is fixed to the cup 110 in a state where there is a gap between an upper end of the mesh ring 150 and a lower end of the sidewall 132 of the inner cup 130. The upper limit of the size of the gap may be arbitrarily set within a range that does not impair the function of the mesh ring 150 as the coating liquid collector. For example, the upper limit may be set to 10 mm or less. A method of fixing the mesh ring 150 to the cup 110 will also be described later.

Further, a position of an outer peripheral surface of the sidewall 132 and a position of an outer peripheral surface of the mesh ring 150 in the radial direction of the cup 110 are substantially the same. A relationship of these positions may be changed as appropriate according to the shape of the inner cup 130 and the like such that a solvent flowing down along an outer peripheral surface of the inner cup 130 drops on the mesh ring 150.

As illustrated in FIGS. 3 and 4, the mesh ring 150 is a cylindrical component such as a cylinder that is open at upper and lower surface portions thereof. As illustrated in FIG. 4, a sidewall 151 of the mesh ring 150 is provided with a plurality of openings 152 through which the exhaust flow passes. These openings 152 are through-holes penetrating from an outer peripheral surface to an inner peripheral surface of the sidewall 151. Further, these openings 152 are formed at intervals along the circumferential direction of the sidewall 151. In the example illustrated in FIGS. 3 and 4, the respective openings 152 are arranged in a zigzag pattern.

FIG. 5 is a longitudinal cross-sectional view of the cup for explaining the mesh ring 150, where white arrows indicate the direction of the exhaust flow. As illustrated in FIG. 5, the exhaust flow flowing in the exhaust path d passes through the openings 152 of the mesh ring 150 and is directed to the exhaust port 144 (FIG. 1). On the other hand, the resist liquid flowing down along the outer peripheral surface of the inner cup 130 or the resist liquid solidified in a filamentous form during a resist coating process does not easily pass through the openings 152 of the mesh ring 150 and stays on the sidewall 151. Thus, the resist liquid, which may become flocculent foreign substances, is collected in the mesh ring 150.

In addition, although the shape of the mesh ring 150 is cylindrical in the present embodiment, the shape of the mesh ring 150 may be changed as appropriate according to the shape of the cup 110. Further, the number, size, arrangement, and the like of the openings 152 of the mesh ring 150 are appropriately determined according to the capacity to collect the resist liquid, the ability to exhaust the cup 110, the shape of the cup 110, and the like.

As illustrated in FIG. 2, a rail 160 extending along the Y direction (horizontal direction in FIG. 2) is formed on the X-direction negative side (down direction in FIG. 2) of the outer cup 120. For example, the rail 160 is formed from the outside of the outer cup 120 on the Y-direction negative side (leftward direction in FIG. 2) to the outside of the outer cup 120 on the Y-direction positive side (rightward direction in FIG. 2). The rail 160 is provided with two arms 161 and 162.

The first arm 161 supports a resist liquid supply nozzle 163 as a coating liquid supplier that supplies a resist liquid as a coating liquid. The resist liquid supplied by the resist liquid supply nozzle 163 has a high viscosity of, for example, 50 cp or more. The first arm 161 is movable on the rail 160 by a nozzle driver 164 as a moving mechanism. Thus, the resist liquid supply nozzle 163 may move from a standby part 165 provided outside the outer cup 120 on the Y-direction positive side to a standby part 166 provided outside the outer cup 120 on the Y-direction negative side by passing above a central portion of the wafer W within the outer cup 120. Further, the first arm 161 may be moved up and down by the nozzle driver 164, so that a height of the resist liquid supply nozzle 163 may be adjusted.

The second arm 162 supports a solvent supply nozzle 167 for supplying an organic solvent such as thinner onto the wafer W. The second arm 162 is movable on the rail 160 by a nozzle driver 169 as a moving mechanism. Thus, the solvent supply nozzle 167 may move from a standby part 168 provided outside the outer cup 120 on the Y-direction positive side to above the central portion of the wafer W within the outer cup 120. The standby part 168 is provided on the Y-direction positive side of the standby part 165. Further, the second arm 162 may be moved up and down by the nozzle driver 169, so that a height of the solvent supply nozzle 167 may be adjusted.

The solvent supplied from the solvent supply nozzle 167 functions as a pre-wet liquid supplied onto the wafer W during a pre-wet processing, which is performed before coating the resist liquid in order to facilitate the spreading of the resist liquid over the wafer W. Further, the solvent from the solvent supply nozzle 167 is shaken off from the wafer W during the pre-wet processing and drops onto the inner cup 130, and the dropped solvent flows down along the outer peripheral surface of the inner cup 130.

Further, as illustrated in FIG. 1, a back rinse liquid supply nozzle 170 for supplying an organic solvent such as thinner to a back side of the wafer W is provided between the inner cup 130 and the spin chuck 101. The solvent supplied from the back rinse liquid supply nozzle 170 is supplied to an end portion of the back side of the wafer W in order to prevent the resist liquid from flowing toward the back side of the wafer W, for example, when spreading the resist liquid over the wafer W. The solvent supplied to the back side of the wafer W drops into the inner cup 130 and flows down along the outer peripheral surface of the inner cup 130.

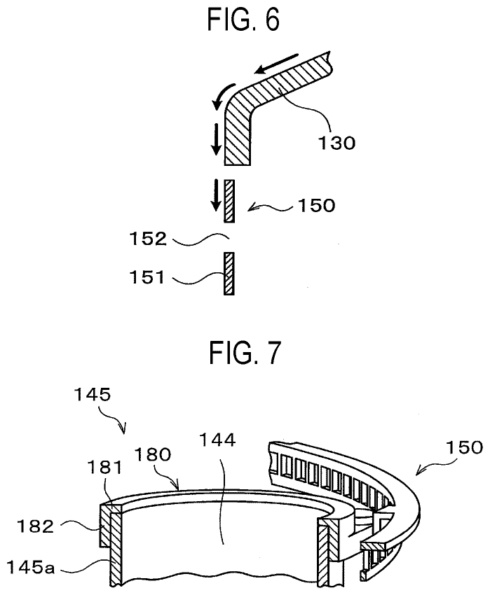

FIG. 6 is a view illustrating an example of a flow of the solvent supplied to the mesh ring 150. In FIG. 6, bold arrows schematically indicate a direction in which the solvent flows. As illustrated in FIG. 6, the solvent flowing down along the outer peripheral surface of the inner cup 130 flows along the sidewall 132 of the inner cup 130 and drops to the mesh ring 150. Thus, the solvent is supplied to the mesh ring 150.

In this way, since the solvent flowing down along the outer peripheral surface of the inner cup 130 is supplied to the mesh ring 150, a device for supplying the solvent to the outer peripheral surface of the inner cup 130 functions as a solvent supplier that supplies the solvent to the mesh ring 150.

In the present embodiment, the solvent supply nozzle 167 and the back rinse liquid supply nozzle 170 described above function as a solvent supplier. The solvent supplier is not limited to these nozzles 167 and 170, and may be, for example, a mechanism for discharging the solvent from a solvent discharge hole (not illustrated) provided inside the inner cup 130 to the outer peripheral surface of the inner cup 130. Also in this case, the solvent flowing down along the outer peripheral surface of the inner cup 130 is supplied to the mesh ring 150. That is, a configuration of the solvent supplier for supplying the solvent to the mesh ring 150 is not particularly limited.

As illustrated in FIG. 1, the resist coating apparatus 1 includes a controller 200. The controller 200 is, for example, a computer equipped with a CPU, a memory, and the like, and includes a program storage (not illustrated). Various programs for controlling a series of resist coating processes for the wafer W in the resist coating apparatus 1 are stored in the program storage. In addition, the programs were recorded on a computer-readable storage medium H, and may be installed from the storage medium H to the controller 200. The storage medium H may be a transitory storage medium or a non-transitory storage medium. A portion or all of the programs may be realized by dedicated hardware (circuit board).

### Fixing of Mesh Ring

Next, a method of fixing the mesh ring 150 will be described.

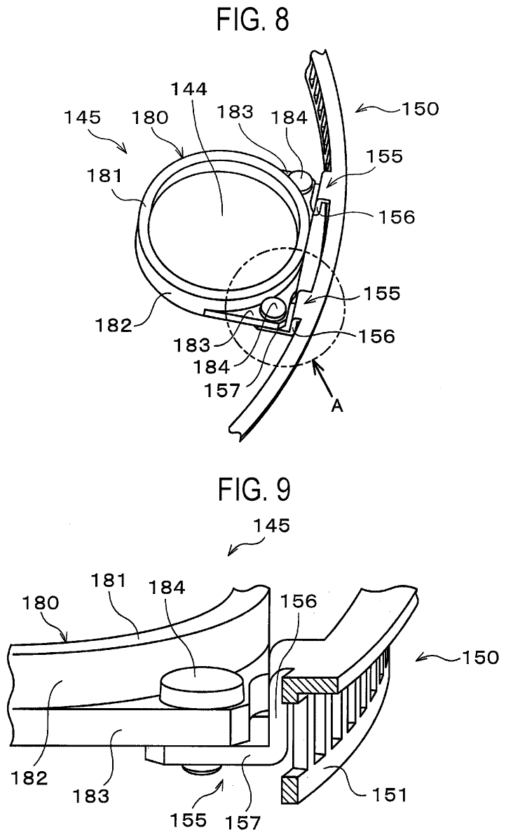

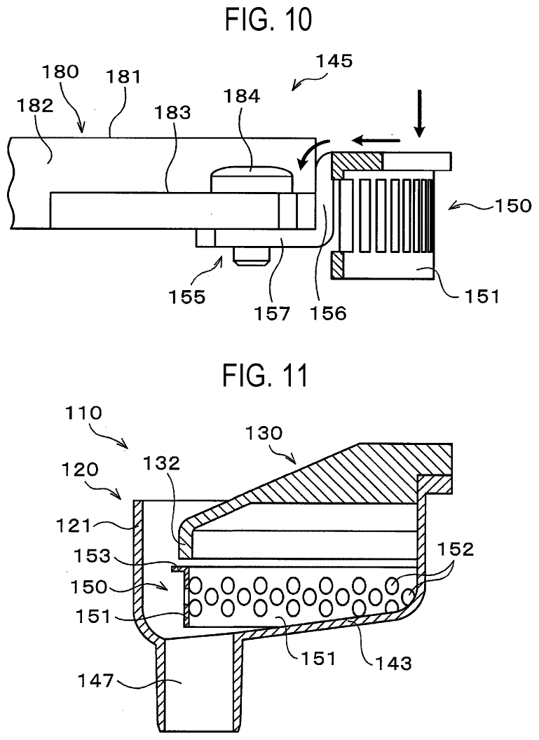

FIG. 7 is an explanatory view for explaining a fixing structure of the mesh ring 150, where a partial cross section of the fixing structure is illustrated. FIG. 8 is an explanatory view for explaining a fixing portion between the mesh ring 150 and an attachment member 180. FIG. 9 is an enlarged view of portion A of FIG. 8. FIG. 10 is a view illustrating an example of flows of a solvent supplied to the mesh ring 150, where bold arrows schematically indicate a direction in which the solvent flows.

As illustrated in FIG. 7, the cylindrical wall portion 145 is composed of a cylindrical main body portion 145a and the attachment member 180 detachably attached to an upper end of the main body portion 145a. The attachment member 180 has a circular ring-shaped upper surface portion 181 and a sidewall portion 182 extending down from an outer peripheral end of the upper surface portion 181.

A material of the attachment member 180 is not particularly limited as long as it is a material having chemical resistance to solvents including, for example, a metal such as stainless steel, but may be a resin. Since the attachment member 180 is formed of a resin, the flexibility of the attachment member 180 is increased, which ensures easy separation of the attachment member 180 from the main body portion 145a.

The attachment member 180 has a shape in which the upper surface portion 181 is in contact with an upper surface of the main body portion 145a and an inner peripheral surface of the sidewall portion 182 is in contact with an outer peripheral surface of the main body portion 145a. In other words, the attachment member 180 has a shape in which it is fitted to the upper end of the main body portion 145a, and is configured to be detachable from the upper end portion of the main body portion 145a. In addition, the form of “attaching the attachment member 180 to the main body portion 145a” herein also includes a form in which the attachment member 180 is fitted to the main body portion 145a as described above.

As illustrated in FIGS. 8 and 9, the sidewall portion 182 is provided with a fixing portion 183 protruding outward from an outer peripheral surface of the sidewall portion 182 for the attachment of the mesh ring 150. This fixing portion 183 is provided at a lower end portion of the sidewall portion 182, so that an upper surface of the fixing portion 183 is positioned lower than the upper surface portion 181. Further, two fixing portions 183 are formed at an interval along the circumferential direction of the sidewall portion 182.

An inner peripheral surface of the mesh ring 150 is provided with bracket portions 155 as fixing portions for attaching the attachment member 180, which are formed at the same interval as the two fixing portions 183 described above. The bracket portion 155 has a wall 156 extending down from the inner peripheral surface of an upper end portion of the sidewall 151, and a horizontal wall 157 protruding inward from a lower end portion of the wall 156. That is, the bracket portion 155 has an L-shaped longitudinal section defined by the walls 156 and 157.

When attaching the attachment member 180 to the mesh ring 150, the fixing portion 183 of the attachment member 180 is superimposed on the wall 157 of the bracket portion 155, and both components are detachably fixed to each other by a bolt 184 as a fastener. In addition, the fastener is not limited to the bolt 184, and may be any of other components such as a hook.

Further, the upper end portion of the main body portion 145a (FIG. 7) is covered with the attachment member 180 having the mesh ring 150 attached thereto, so that the mesh ring 150 is detachably fixed to the cylindrical wall portion 145.

The method of fixing the mesh ring 150 to the cylindrical wall portion 145 has been described above.

The resist coating apparatus 1 according to the present embodiment can collect the resist liquid flowing down along the outer peripheral surface of the inner cup 130 or the resist liquid solidified in a filamentous form during the resist coating process by the mesh ring 150 arranged below the sidewall 132 of the inner cup 130.

After that, the solvent, which is supplied to the wafer W at a timing before or after the resist coating process, flows down along the outer peripheral surface of the inner cup 130, so that the solvent can be supplied to the mesh ring 150. Then, the solvent supplied to the mesh ring 150 comes into contact with the resist liquid or a solidified substance of the resist liquid collected in the mesh ring 150, thereby diluting the resist liquid or dissolving the solidified substance of the resist liquid. Thus, the resist liquid or the solidified substance of the resist liquid collected in the mesh ring 150 becomes easy to be discharged, which makes it easy to be discharged from the liquid discharge port 147. As a result, the clogging of the exhaust path such as the exhaust port 144 or the exhaust pipe 146 with foreign substances may be prevented.

Further, according to the structure in which the mesh ring 150 is fixed to the cylindrical wall portion 145, the attachment and detachment of the mesh ring 150 are facilitated in a cup having a general structure, which results in improved maintenance workability. Further, for example, since it is easy to replace an existing mesh ring that requires maintenance with a new mesh ring, the time to stop the operation of the resist coating apparatus 1 may be shortened, which may improve the productivity of the wafer W to be resist-coated.

Furthermore, in the structure in which the mesh ring 150 is fixed to the cylindrical wall portion 145, the mesh ring 150 may be provided not only when the resist coating apparatus 1 is newly manufactured, but also for an existing resist coating apparatus including no mesh ring 150. Therefore, the effect of preventing the clogging of the exhaust path and the effect of excellent maintenance workability described above may be obtained at low cost.

By the way, in the method of fixing the mesh ring 150 described above, the solvent dropped to the mesh ring 150 flows along the sidewall 151, but at a location where the bracket portion 155 is formed, as illustrated in FIG. 10, the solvent flows to the bracket portion 155. On the other hand, the fixing portion between the mesh ring 150 and the cylindrical wall portion 145 (the fastening portion by the bolt 184 between the mesh ring 150 and the attachment member 180) is positioned lower than the upper end of the cylindrical wall portion 145 (that is, the upper end of the attachment member 180).

Therefore, the solvent, which has dropped to the mesh ring 150 and has flown to the bracket portion 155, flows along the walls 156 and 157, drops from the wall 157, and is discharged. That is, when the fixing portion between the mesh ring 150 and the cylindrical wall portion 145 is positioned lower than the upper end of the cylindrical wall portion 145, the solvent flowing from the mesh ring 150 toward the cylindrical wall portion 145 may be prevented from flowing into the exhaust port 144 (FIG. 7).

In addition, the mesh ring 150 may be fixed so as not to come into contact with the cup 110 except for the fixing portion between the mesh ring 150 and the cylindrical wall portion 145 (the fixing portion between the mesh ring 150 and the attachment member 180 in the example of FIG. 7). Thus, the resist liquid is prevented from staying in a gap between the mesh ring 150 and the cup 110, which may prevent sticking of components due to solidification of the resist liquid.

In particular, when the mesh ring 150 is not in contact with the bottom member 143 of the cup 110 (FIG. 1), the resist liquid diluted with the solvent or a solution of the filamentous or flocculent foreign substances dissolved by the solvent is easy to be discharged.

Further, in the above example, the structure in which the cylindrical attachment member 180 is fitted to the main body portion 145a of the cylindrical wall portion 145 has been described, but the shape of the attachment member 180 is not particularly limited as long as it is detachably attached to the main body portion 145a. Further, the position where the attachment member 180 is attached to the main body portion 145a is not limited to the upper end portion of the main body portion 145a, and may be, for example, a central portion or lower end of the main body portion 145a in the vertical direction. That is, the attachment position between the main body portion 145a and the attachment member 180 is not particularly limited as long as the mesh ring 150 can be fixed to the main body portion 145a.

Further, the mesh ring 150 may be fixed to the main body portion 145a of the cylindrical wall portion 145 without providing the attachment member 180 described above. On the other hand, the attachment member 180 may be provided, for example, when it is difficult to directly couple the mesh ring 150 to the main body portion 145a, or when the mesh ring 150 of the same specification is attached to the cup 110 of other models having a different shape of the exhaust port 144.

For example, if a plurality of attachment members 180 manufactured according to the shape of the exhaust port 144 are prepared, the mesh ring 150 of the same specification may be replaced and fitted to each attachment member 180, so that the mesh ring 150 of the same specification may be applied to the resist coating apparatuses 1 having different structures. Thus, it may be unnecessary to manufacture the dedicated mesh ring 150 for each resist coating apparatus.

When the attachment member 180 is not provided, the fixing portion (not illustrated) between the mesh ring 150 and the main body portion 145a of the cylindrical wall portion 145 may be positioned lower than the upper end of the cylindrical wall portion 145 (that is, the upper end of the main body portion 145a). Thus, the solvent flowing to the fixing portion between the mesh ring 150 and the cylindrical wall portion 145 is easy to be discharged without overflowing the upper end of the cylindrical wall portion 145, which prevents the solvent from flowing into the exhaust port 144.

The schematic configuration of the resist coating apparatus 1 according to the embodiment has been described above. Next, another configuration example of the cylindrical mesh ring 150 will be described.

### Liquid Receiver

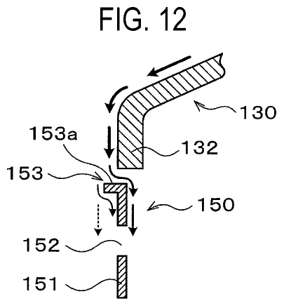

FIG. 11 is a longitudinal cross-sectional view of the cup 110 illustrating a liquid receiver 153. FIG. 12 is a view illustrating an example of flows of the solvent supplied to the mesh ring 150, in which bold arrows schematically indicate a direction in which the solvent flows.

As illustrated in FIG. 11, the cylindrical mesh ring 150 may include the liquid receiver 153 at the upper end portion of the sidewall 151. The liquid receiver 153 is a horizontal portion formed in a circular ring-shaped shape. An outer peripheral end of the liquid receiver 153 protrudes outward (toward the outer cup 120) from the outer peripheral surface of the sidewall 151. Further, the outer peripheral end of the liquid receiver 153 is located outward of the outer peripheral surface of the sidewall 132 of the inner cup 130.

In addition, the sidewall 151 and the liquid receiver 153 may be an integral body obtained by integral molding, or may be configured by assembling a plurality of components. The liquid receiver 153 does not have to be a horizontal shape, but may have a horizontal shape from the viewpoint of ease of processing, for example, when the sidewall 151 and the liquid receiver 153 are formed as one component by processing a metal plate such as stainless steel.

As illustrated in FIG. 12, when the liquid receiver 153 is provided, the solvent flowing down along the outer peripheral surface of the inner cup 130 drops from the lower end of the sidewall 132 onto the liquid receiver 153. Therefore, the liquid receiver 153 may receive and collect even the solvent which would not reach the sidewall 151 in the absence of the liquid receiver 153.

Then, the solvent dropped onto the liquid receiver 153 flows toward an inner peripheral end or an outer peripheral end of an upper surface of the liquid receiver 153 (liquid receiver surface 153a). The solvent directed to the inner peripheral end of the liquid receiver surface 153a is supplied to the inner peripheral surface of the sidewall 151 from the inner peripheral end. On the other hand, the solvent directed to the outer peripheral end of the liquid receiver surface 153a flows along a lower surface of the liquid receiver 153 and is supplied to the outer peripheral surface of the sidewall 151.

In this way, when the mesh ring 150 includes the liquid receiver 153, more of the solvent flowing down along the outer peripheral surface of the inner cup 130 may be collected, and may be supplied to the mesh ring 150. Therefore, the dilution of the resist liquid or the dissolution of the solidified substance of the resist liquid, collected in the mesh ring 150, is promoted, which makes it possible to enhance the effect of preventing the clogging of the exhaust path with foreign substances.

In addition, the shape of the liquid receiver 153 is not limited to the L-shape as illustrated in FIG. 12, and may be, for example, a T-shape. On the other hand, while the cup 110 is being exhausted, the exhaust flow is formed in a direction from an outer peripheral side to an inner peripheral side of the mesh ring 150 (direction from left to right in FIG. 12). Therefore, when the liquid receiver 153 has the T-shape, the solvent flowing along the inner peripheral end of the liquid receiver 153 may be affected by the exhaust flow and may have difficulty in reaching the sidewall 151.

Accordingly, as illustrated in FIG. 12, when the outer peripheral end of the liquid receiver 153 protrudes outward from the sidewall 132 of the inner cup 130, the inner peripheral end of the liquid receiver 153 and the inner peripheral surface of the sidewall 151 may be continuous without a step. This makes it easier to supply the solvent to the sidewall 151 from the inner peripheral end of the liquid receiver 153 compared to the T-shaped liquid receiver.

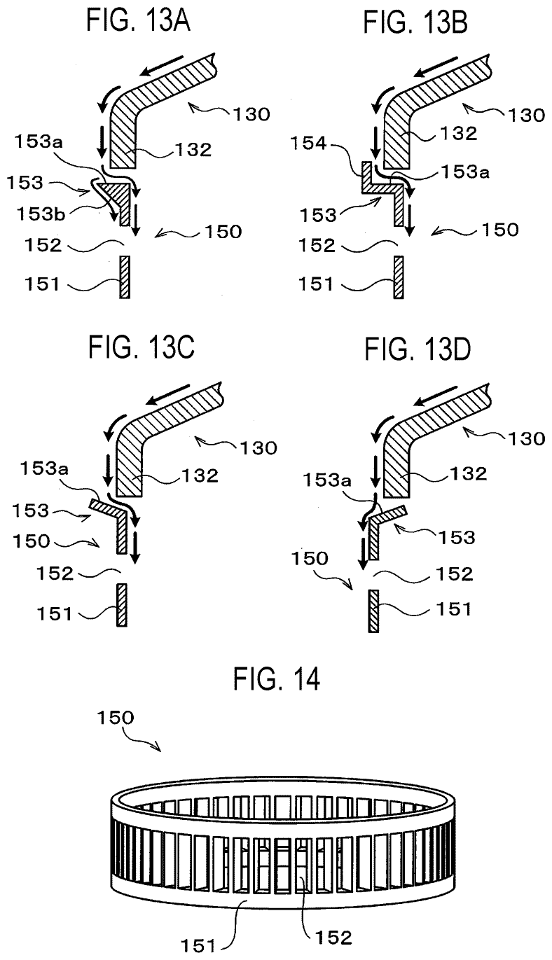

Further, the liquid receiver 153 may have, for example, any of shapes illustrated in FIGS. 13A to 13D.

FIG. 13A is an example in which the outer peripheral end of the liquid receiver 153 and the outer peripheral surface of the sidewall 151 are connected to each other by an inclined surface 153b. In the above-described liquid receiver 153 illustrated in FIG. 12, a portion of the solvent may drop from the outer peripheral end of the liquid receiver 153 as indicated by the dotted line arrow in FIG. 12, so that the solvent may not be supplied to the sidewall 151. On the other hand, according to the liquid receiver 153 having the inclined surface 153b illustrated in FIG. 13A, since the solvent flowing down from the outer peripheral end of the liquid receiver surface 153a is easy to flow along the inclined surface 153b, which may increase the amount of solvent supplied to the sidewall 151.

FIG. 13B is an example in which a sidewall 154 extending upward from the liquid receiver 153 is provided at the outer peripheral end of the liquid receiver 153. The sidewall 154 is a cylindrical wall, and the solvent flowing down along the outer peripheral surface of the inner cup 130 drops onto the liquid receiver surface 153a on an inner peripheral side of the sidewall 154. Then, the solvent dropped onto the liquid receiver surface 153a flows toward the inner peripheral end of the liquid receiver surface 153a, without dropping from the outer peripheral end of the liquid receiver surface 153a, due to the presence of the sidewall 154. That is, according to the liquid receiver 153 illustrated in FIG. 13B, the solvent, which would otherwise have dropped from the outer peripheral end of the liquid receiver surface 153a, may also be supplied to the sidewall 151.

FIG. 13C is an example in which the outer peripheral end of the liquid receiver surface 153a is higher than the inner peripheral end thereof, and the liquid receiver surface 153a is inclined down from the outer peripheral end to the inner peripheral end. According to the liquid receiver 153 illustrated in FIG. 13C, the solvent dropped onto the liquid receiver surface 153a flows down toward the inner peripheral end of the liquid receiver surface 153a and becomes difficult to drop from the outer peripheral end of the liquid receiver surface 153a. Thus, the amount of solvent supplied from the liquid receiver surface 153a of the mesh ring 150 toward the inner peripheral surface of the sidewall 151 may be increased.

FIG. 13D is an example in which the outer peripheral end of the liquid receiver surface 153a is lower than the inner peripheral end thereof, and the liquid receiver surface 153a is inclined upward from the outer peripheral end to the inner peripheral end. According to the liquid receiver 153 illustrated in FIG. 13D, the solvent dropped onto the liquid receiver surface 153a flows down toward the outer peripheral end of the liquid receiver surface 153a and becomes difficult to drop from the inner peripheral end of the liquid receiver surface 153a. Thus, the amount of solvent supplied from the liquid receiver surface 153a of the mesh ring 150 toward the outer peripheral surface of the sidewall 151 may be increased.

### Shape Example of Opening

Next, other shape examples of the openings 152 will be described. FIG. 14 is a perspective view of the mesh ring 150.

The openings 152 illustrated in FIG. 14 have a rectangular shape, short sides of which are located at upper and lower ends of the opening 152. Further, the opening 152 extends from an upper end portion to a lower end portion of the sidewall 151 of the mesh ring 150. The respective openings 152 are arranged at intervals along the circumferential direction of the mesh ring 150.

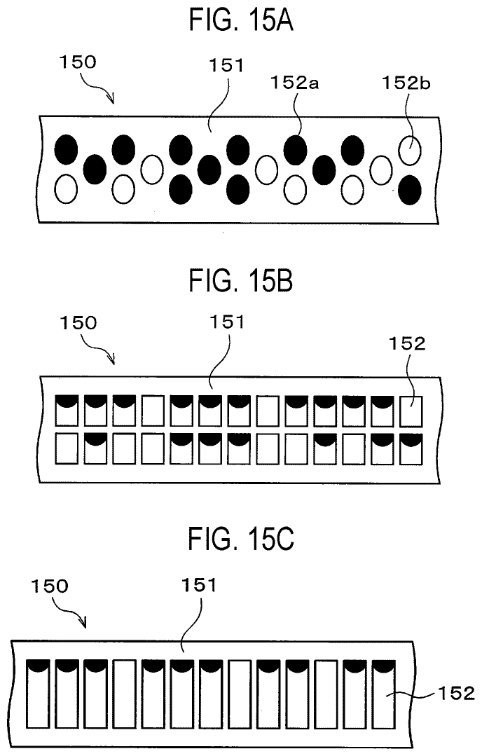

When the openings 152 have such a shape, it is possible to prevent the openings 152 from being blocked by the solvent supplied to the mesh ring 150 and to make it easy to maintain a desired exhaust pressure upon the evacuation of the cup. The reason for this will be explained below with reference to FIGS. 15A to 15C.

FIGS. 15A to 15C are views illustrating an example of states of the solvent remaining in the opening 152, and the black circles in the drawings schematically illustrate the solvent remaining in the openings 152.

The solvent supplied to the mesh ring 150 may remain adhered to the sidewall 151 or the openings 152 of the mesh ring 150 without being discharged. At this time, as illustrated in FIG. 15A, in a case where a shape of an upper end of the opening 152 is not horizontal such as an ellipse or a circle, a liquid film of the solvent is likely to be formed in the opening 152 when the solvent flowing down from top to bottom of the sidewall 151 passes through the opening 152.

Even if there is an opening 152a blocked by the liquid film, there is also an opening 152b that is open without the liquid film being formed. Thus, the resist coating process described above can be performed. However, the number of openings 152b through which the exhaust flow may pass is relatively reduced when the blocked opening 152a exists, so that it is difficult to maintain a desired exhaust pressure upon the evacuation of the cup. Therefore, in order to perform the resist coating process while maintaining the exhaust capacity of the cup within an allowable range, it is necessary to increase the frequency of maintenance for removing the liquid film from the blocked opening 152a.

On the other hand, as illustrated in FIG. 15B, when the shape of the upper end of the opening 152 is horizontal, a liquid film that blocks the opening 152 is less likely to be formed. Therefore, the upper end of the opening 152 may be formed horizontally.

Further, the opening 152 may have a rectangular shape, and short sides thereof may be located at the upper and lower ends of the opening 152, as illustrated in FIG. 15B. Thus, formation of the liquid film by the solvent supplied to the mesh ring 150 may be further prevented.

On the other hand, when a plurality of rectangular openings 152 are arranged in the height direction of the mesh ring 150 as illustrated in FIG. 15B, there are cases where solvent droplets are formed in the respective openings 152 arranged in the height direction.

Therefore, the rectangular opening 152 may extend from the upper end portion to the lower end portion of the sidewall 151 of the mesh ring 150, as illustrated in FIG. 15C in addition to FIG. 14 described above. Thus, the number of openings 152 arranged in the height direction is reduced, and locations where the solvent droplets are likely to occur are also reduced. As a result, even if the solvent droplets are formed in the openings 152, a reduction in the opening area of the mesh ring 150 as a whole may be prevented. Therefore, a desired exhaust pressure may be easily maintained even if the frequency of maintenance of the mesh ring 150 is reduced.

### Annular Mesh Ring

In the above example, the cylindrical mesh ring 150 has been described, but the mesh ring 150 may have an annular shape, for example, a circular ring-shaped shape.

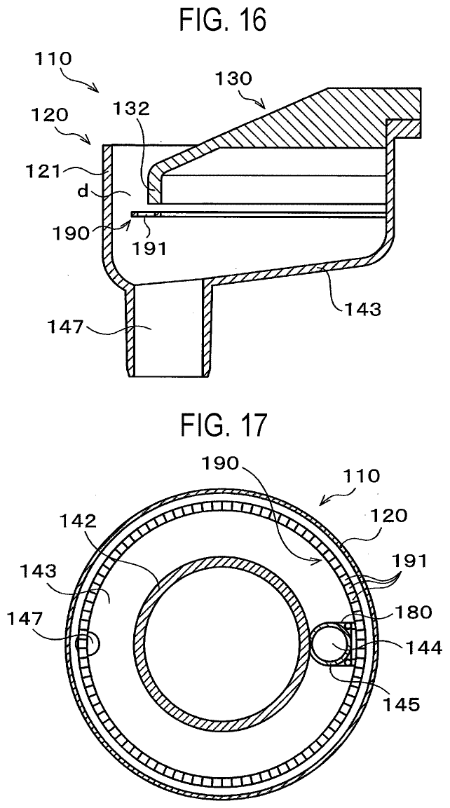

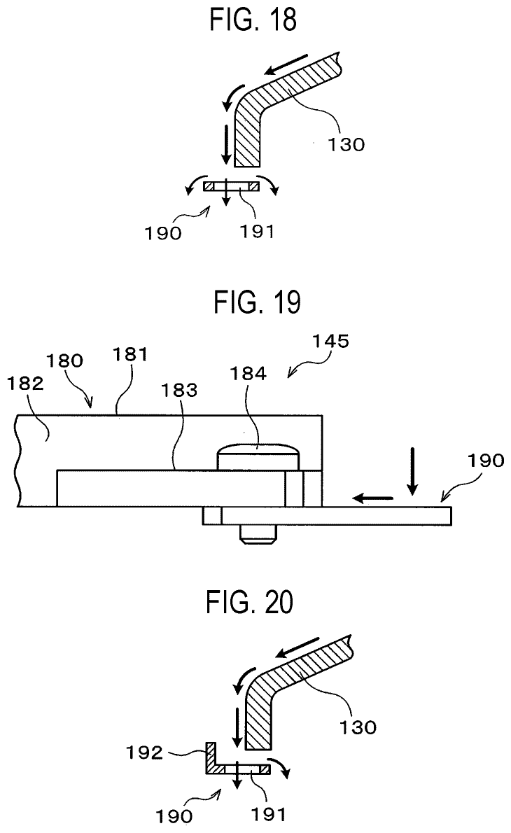

FIG. 16 is a longitudinal cross-sectional view of a cup for explaining an annular mesh ring. FIG. 17 is a transversal cross-sectional view of the cup for explaining the annular mesh ring. FIG. 18 is a view illustrating an example of flows of a solvent supplied to the annular mesh ring, in which bold arrows schematically indicate a direction in which the solvent flows.

An annular mesh ring 190 illustrated in FIG. 16 is arranged below the sidewall 132 of the inner cup 130 while being spaced apart from the lower end of the sidewall 132. As illustrated in FIG. 17, the mesh ring 190 is fixed to the cylindrical wall portion 145 via the attachment member 180. An opening 191 through which the exhaust flow passes is formed so as to penetrate from an upper surface to a lower surface of the mesh ring 190. A plurality of openings 191 are provided at intervals along the circumferential direction of the mesh ring 190. Further, an outer peripheral end of the mesh ring 190 protrudes outward (toward the outer cup 120) from the outer peripheral surface of the sidewall 132 of the inner cup 130.

Such an annular mesh ring 190 may also collect the resist liquid flowing down along the outer peripheral surface of the inner cup 130 or the resist liquid solidified in a filamentous form during the resist coating process. Further, as illustrated in FIG. 18, the solvent flowing down along the outer peripheral surface of the inner cup 130 is supplied to the mesh ring 190. Thus, the dilution of the resist liquid or the dissolution of the resist liquid solidified in a filamentous form, collected in the mesh ring 190, is performed.

Further, as illustrated in FIG. 19, when a fixing portion (fastening portion by the bolt 184) between the mesh ring 190 and the attachment member 180 is positioned lower than the upper end of the cylindrical wall portion 145 (the upper end of the attachment member 180), the solvent flowing from the mesh ring 190 toward the cylindrical wall portion 145 may be prevented from flowing into the exhaust port 144 (FIG. 17).

Further, as illustrated in FIG. 20, the annular mesh ring 190 may be provided with a sidewall 192 as a cylindrical wall which extends upward from an outer peripheral end portion of a surface where the opening 191 is formed. Thus, the solvent that has flown down from the inner cup 130 is easy to flow toward an inner peripheral end portion of the surface where the opening 191 is formed, which may promote the dilution of the resist liquid remaining at a position close to the exhaust side and the dissolution of the solidified substance of the resist liquid.

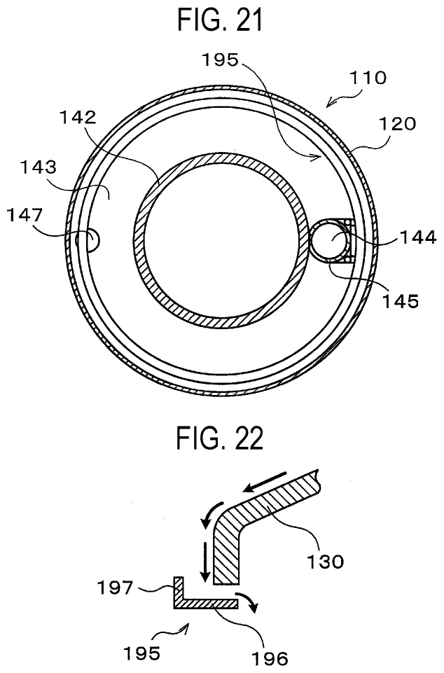

In addition, in the above description, the mesh rings 150 and 190 have been illustrated as the coating liquid collector, but the coating liquid collector is not particularly limited as long as it has a structure capable of collecting the resist liquid. For example, the coating liquid collector may be an annular plate 195 as illustrated in FIGS. 21 and 22, which does not have the opening 191 of the annular mesh ring 190 illustrated in FIGS. 16 to 20.

The annular plate 195 is formed of a metal plate such as stainless steel. The annular plate 195 receives and collects the resist liquid dropping from the inner cup 130 in a horizontal portion 196. In such an annular plate 195 as well, the solvent flowing down from the inner cup 130 may dilute the resist liquid collected in the annular plate 195 and may dissolve the solidified substance of the resist liquid, thereby preventing clogging of the exhaust path with foreign substances.

Further, as illustrated in FIG. 22, the annular plate 195 may be provided with a sidewall 197 as a cylindrical wall which extends upward from an outer peripheral end portion of the horizontal portion 196.

The liquid processing apparatus according to the present disclosure has been described above by taking the resist coating apparatus 1 as an example. In addition, the liquid processing apparatus according to the present disclosure may also be applied to liquid processing apparatuses for processing target substrates other than semiconductor wafers, such as flat panel display (FPD) substrates and mask reticles for photomasks.

According to the present disclosure in some embodiments, it is possible to prevent clogging of an exhaust path by foreign substances generated during a spin coating process of a substrate.

The embodiments disclosed herein should be considered to be exemplary and not limitative in all respects. The above embodiments may be omitted, replaced, or modified in various forms without departing from the scope of the appended claims, configuration examples within the technical scope of the present disclosure, and the gist thereof. For example, the constituent elements of the above embodiments may be arbitrarily combined. From this arbitrary combination, actions and effects related to each element of the combination are naturally obtained, and other actions and effects that are clear to those skilled in the art from the description in this specification are obtained.

Further, the effects described herein are merely illustrative or exemplary and not limiting. In other words, the technology of the present disclosure may produce other effects that are clear to those skilled in the art from the description of this specification in addition to or instead of the above effects.

In addition, the following configuration examples also belong to the technical scope of the present disclosure.

(1) A liquid processing apparatus for applying a coating liquid onto a substrate includes:
a substrate holder configured to hold and rotate the substrate; a coating liquid supplier configured to supply the coating liquid to the substrate held by the substrate holder; a cup surrounding the substrate held by the substrate holder; and a solvent supplier configured to supply a solvent for the coating liquid to a coating liquid collector, wherein the cup includes: an outer cup arranged outside the substrate holder; an inner cup arranged on an inner peripheral side of the outer cup and below the substrate holder, the inner cup having a downwardly-extending wall; an exhaust path provided between the outer cup and the inner cup; a cylindrical wall portion provided below the inner cup and having an upwardly-opened exhaust port communicating with the exhaust path; and the coating liquid collector arranged below the downwardly-extending wall of the inner cup with a gap between the coating liquid collector and a lower end of the downwardly-extending wall, the coating liquid collector being fixed to the cylindrical wall portion.

(2) In the liquid processing apparatus of (1) above, a fixing portion between the coating liquid collector and the cylindrical wall portion is located lower than an upper end of the cylindrical wall portion.

(3) In the liquid processing apparatus of (1) or (2) above, the cylindrical wall portion includes: a cylindrical main body portion; and an attachment member detachably attached to the cylindrical main body portion, the coating liquid collector is attached to the attachment member, and the fixing portion corresponds to a fixing portion between the coating liquid collector and the attachment member.

(4) In the liquid processing apparatus of any one of (1) to (3) above, the attachment member is formed of a resin.

(5) In the liquid processing apparatus of any one of (1) to (4) above, the coating liquid collector is not in contact with the cup except for the fixing portion between the coating liquid collector and the cylindrical wall portion.

(6) In the liquid processing apparatus of any one of (1) to (5) above, the coating liquid collector has a cylindrical or annular shape and is provided with a plurality of openings through which an exhaust flow passes.

What is claimed is:

1. A liquid processing apparatus that supplies a processing liquid onto a substrate, comprising:
a substrate holder configured to hold and rotate the substrate;
a processing liquid supplier configured to supply the processing liquid to the substrate held by the substrate holder; and
a cup provided to surround the substrate held by the substrate holder,
wherein the cup includes:
an outer cup arranged outside the substrate holder;
an inner cup arranged on an inner peripheral side of the outer cup and below the substrate holder, the inner cup having a downwardly-extending wall;
an exhaust path provided between the outer cup and the inner cup;
an upwardly-opened exhaust port provided below the inner cup and communicating with the exhaust path; and
the processing liquid collector arranged below the downwardly-extending wall of the inner cup with a gap between the processing liquid collector and a lower end of the downwardly-extending wall, and
wherein the processing liquid collector is fixed to the upwardly-opened exhaust port.

2. The liquid processing apparatus of claim 1, wherein the processing liquid collector is fixed to a cylindrical wall portion provided having the upwardly-opened exhaust port, and
a fixing portion between the processing liquid collector and the cylindrical wall portion is located lower than an upper end of the cylindrical wall portion.

3. The liquid processing apparatus of claim 2, wherein the cylindrical wall portion includes:
a cylindrical main body portion; and
an attachment member detachably attached to the cylindrical main body portion,
wherein the processing liquid collector is attached to the attachment member, and
wherein the fixing portion corresponds to a fixing portion between the processing liquid collector and the attachment member.

4. The liquid processing apparatus of claim 3, wherein the attachment member is formed of a resin.

5. The liquid processing apparatus of claim 3, wherein the processing liquid collector is not in contact with the cup except for the fixing portion between the processing liquid collector and the cylindrical wall portion.

6. The liquid processing apparatus of claim 3, wherein the processing liquid collector has a cylindrical or annular shape and is provided with a plurality of openings through which an exhaust flow passes.

7. The liquid processing apparatus of claim 1, wherein the processing liquid collector is not in contact with the cup except for a fixing portion between the processing liquid collector and a cylindrical wall portion.

8. The liquid processing apparatus of claim 1, wherein the processing liquid collector has a cylindrical or annular shape and is provided with a plurality of openings through which an exhaust flow passes.
